(19) United States
(12) Patent Application Publication
(10) Pub. No.: US 2011/0248155 A1
(43) Pub. Date: Oct. 13, 2011

(54) DISTRIBUTED FILTERING AND SENSING STRUCTURE AND OPTICAL DEVICE CONTAINING THE SAME

(75) Inventor: Kuan-Ren CHEN, TAINAN CITY (TW)

(73) Assignee: NATIONAL CHENG KUNG UNIVERSITY, TAINAN CITY (TW)

(21) Appl. No.: 13/083,596

(22) Filed: Apr. 11, 2011

Related U.S. Application Data
(60) Provisional application No. 61/322,921, filed on Apr. 12, 2010.

(51) Int. Cl. H01J 40/14

(52) U.S. Cl. 250/226

(57) ABSTRACT

A distributed filtering and sensing structure includes a base board divided into a plurality of regions, and more than ten filtering and sensing modules distributed on the respective sections, wherein the total area occupied by the filtering and sensing modules is less than one half of the total area of the regions, wherein each filtering and sensing module is used to receive a first electromagnetic wave with a first wavelength range. Each filtering and sensing module includes a non-organic filtering element for filtering the first electromagnetic wave to obtain a second electromagnetic wave with a second wavelength range; an electromagnetic sensor disposed under the non-organic filtering device for receiving the second electromagnetic wave; and an electron/hole collecting module electrically connected to the electromagnetic sensor. The second wavelength range is part of the first wavelength range. Furthermore, the distributed filtering and sensing structure can be applied on an optical device.

### CROSS-REFERENCE TO RELATED APPLICATION

This application claims the priority benefit of U.S. Provisional Application Ser. No. 61/322,921, filed on Apr. 12, 2010, the full disclosures of which are incorporated herein by reference.

### BACKGROUND

1. Field of Invention

The present invention relates to a filtering and sensing structure and an optical device containing the filtering and sensing structure. More particularly, the present invention relates to a distributed filtering and sensing structure including a non-organic filtering element and an electromagnetic wave sensor, and to an optical device containing the filtering and sensing structure.

2. Description of Related Art

With the advance of networking technologies, more and more bandwidth is available, and thus the network instant communication among people has gradually entering an era of network video telephony in which both sound and image are transmitted, instead of network sound-only telephony.

A conventional network video telephony generally requires a sound receiving device (such as a microphone), a sound propagation device (such as a speaker), an image capturing device (such as a camera), an image displaying device (such as a liquid crystal display (LCD)) and a signal processing device (such as a computer) for enabling network video communication, wherein the signal processing device is used to connect to Internet and process the sound and image signals captured by the sound receiving device and the image capturing device, and then to transmit those signals to another remote signal processing device. By using the remote signal processing device, these signals can be converted back to the sound and image via a remote sound propagation device and a remote image displaying device, thus enabling the network video communication.

In the conventional network video telephony, a detached image capturing device can be used, wherein the image capturing device is disposed on the top of the frame of the image displaying device. Besides, an integrated image capturing device also can be used in the conventional network video telephony, wherein the image capturing device is generally disposed on the display surface of the image displaying device, and is adjacent to the top of the frame of the image displaying device. Therefore, the functions of capturing and displaying an image can be achieved.

However, in the above two structures of using the respective detached and integrated image capturing devices, since the image capturing devices in general are disposed above the horizontal surface on which a user's visual line is located, two users at two different places cannot stare at each other through such devices. Further, the structure of using the detached image capturing device has the disadvantage of complicated implementation.

Moreover, in the conventional image capturing device, a filtering element for filtering incident light is generally formed from an organic material. However, under long-term irradiation of electromagnetic wave or charged particles, such an organic filtering element has the disadvantage of short operation life.

### SUMMARY

Therefore, an object of the present invention is to provide a distributed filtering and sensing structure and an optical device containing the distributed filtering and sensing structure for overcoming the aforementioned disadvantages. In the optical device, a plurality of filtering and sensing modules distributed on a plurality of regions of a base board are included, and each filtering and sensing module includes a non-organic filtering element and an electromagnetic sensor disposed under the non-organic filtering element. The electromagnetic sensors are used to achieve the function of an image capturing devices, i.e. the image capturing devices are distributed on the regions of the optical device (such as a display surface of an image displaying device). Thus, when the image displaying device adopting the distributed filtering and sensing structure of the present invention is used to conduct video telephone communication, the aforementioned disadvantages of users failing to stare at each other and complicated implementation can be overcome. Further, using a non-organic material to fabricate the filtering element of the distributed filtering and sensing structure can overcome the aforementioned disadvantage of short operation life.

According to an embodiment of the present invention, a distributed filtering and sensing structure is provided and includes a base board divided into divided into a plurality of regions; and a plurality of filtering and sensing modules distributed on the regions of the base board, wherein the total number of the filtering and sensing modules is greater than ten, and the total area occupied by the filtering and sensing modules is smaller than one half of the total area of the regions. Each of the filtering and sensing modules is used for receiving a first electromagnetic wave with a first wavelength range, and includes a non-organic filtering element, an electromagnetic sensor and an electron/hole collecting module electrically connected to the electromagnetic sensor. The non-organic filtering element is used for filtering the first magnetic wavelength to obtain a second electromagnetic wave with a second wavelength range, wherein the second wavelength range is part of the first wavelength range. The electromagnetic sensor is disposed under the non-organic filtering element for receiving the second electromagnetic wave.

According to another embodiment of the present invention, an optical device is provided and includes the aforementioned distributed filtering and sensing structure.

The present invention advantageously adopts a non-organic material (such as a metallic material) to fabricate the filtering element for prolonging the operation life of the electromagnetic filtering element, and the electromagnetic filtering element with prolonged operation life further prevents the electromagnetic sensor disposed thereunder from being damaged by receiving too much electromagnetic wave or too many charged particles, thus assuring the distributed filtering and sensing structure or the optical device containing the distributed filtering and sensing structure to be operated normally. Further, when the material forming the electromagnetic filtering element is a metallic material, various etching techniques can be used to form various patterns (such as slits, holes or meshes, etc.) desired by the electromagnetic filtering element. Thus, in comparison with the conventional skills using the organic material to form the electromagnetic filtering element, using the metallic material to form the electromagnetic filtering element has the advantage of simple manufacturing process.

It is to be understood that both the foregoing general description and the following detailed description are examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1A is a schematic top view showing a distributed filtering and sensing structure according to an embodiment of the present invention;

FIG. 1B is a schematic side view showing the distributed filtering and sensing structure shown in FIG. 1A;

FIG. 1C is a schematic side view showing a distributed filtering and sensing structure according to another embodiment of the present invention;

FIG. 2 is a schematic side view showing a distributed filtering and sensing structure according to yet another embodiment of the present invention;

FIG. 3 to FIG. 10 are schematic side views each of which shows one single pixel unit in a light emitting diode (LED) display device according to respective embodiments of the present invention;

FIG. 11 to FIG. 13 are schematic side views each of which shows one single pixel unit in an organic light emitting diode (OLED) display device according to respective embodiments of the present invention;

FIG. 14 to FIG. 18 are schematic side views each of which shows one single pixel unit in a liquid crystal display (LCD) device according to respective embodiments of the present invention;

FIG. 19 is a schematic side view showing one single pixel unit in a plasma display device according to one embodiment of the present invention; and

FIG. 20 to FIG. 22 are schematic side views each of which shows one single pixel unit in a liquid crystal on silicon (LCOS) device according to respective embodiments of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

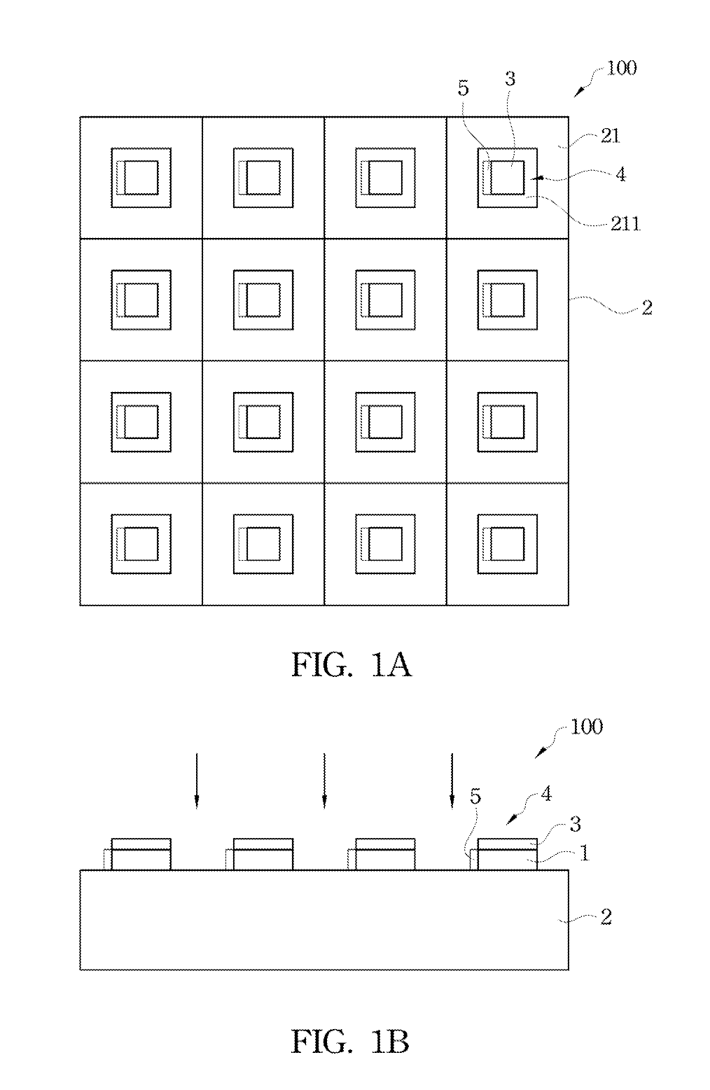

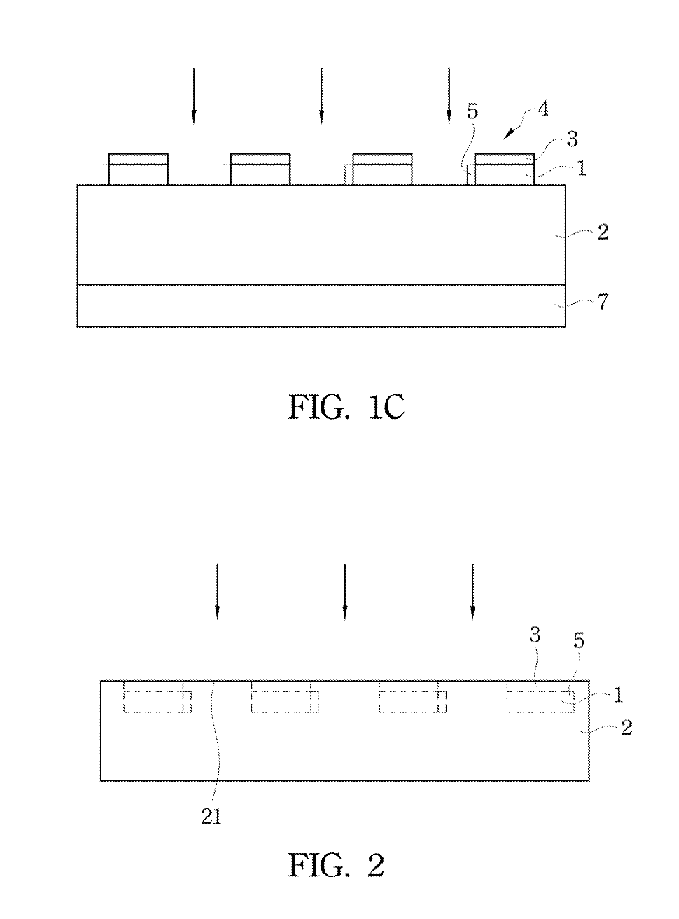

Referring to FIG. 1A to FIG. 1B, FIG. 1A is a schematic top view showing a distributed filtering and sensing structure according to an embodiment of the present invention, and FIG. 1B is a schematic side view showing the distributed filtering and sensing structure shown in FIG. 1A. In the present embodiment, a distributed filtering and sensing structure 100 includes a base board 2 and a plurality of filtering and sensing modules 4. The base board 2 is mainly used for disposing other components of the distributed filtering and sensing structure 100 in addition to the filtering and sensing modules 4, and is divided into a plurality of regions 21, wherein, for example, as shown in FIG. 1A, the respective areas (dimensions) of the regions 21 are the same. However, in other specific embodiments, the respective areas (dimensions) of the regions 21 can be different, and can be adjusted in accordance with the requirements of the distributed filtering and sensing structure 100.

In the distributed filtering and sensing structure 100, the plurality of filtering and sensing modules 4 are distributed in the regions 21, and can be disposed on the surface of the base board 2 or inside the base board 2, wherein the total number of the filtering and sensing modules 4 is greater than ten, and the total area of the base board 2 occupied by the filtering and sensing modules 4 is smaller than one half of the total area of the regions 21, thereby preventing other functions (such as the display function of a display using the distributed filtering and sensing structure 100) from being interfered by the filtering and sensing modules 4. In the present embodiment, each region 21 includes one filtering and sensing modules 4 and the area occupied by one filtering and sensing modules 4 is smaller than one half of the area of one region 21. However, in other specific embodiments, more than one filtering and sensing modules 4 or none can be included in one of the regions 21. Besides, each filtering and sensing module 4 is used for receiving a first electromagnetic wave (shown by the downward arrows in FIG. 1B) with a first wavelength range, wherein the first electromagnetic wave is an incident electromagnetic wave received by the distributed filtering and sensing structure 100.

In the present embodiment, each filtering and sensing module 4 includes a non-organic filtering element 3, an electromagnetic sensor 1 and an electron/hole collecting module 5. The non-organic filtering element 3 can be formed from various patterns such as slits, holes or meshes, etc., and is mainly used for filtering the first electromagnetic wave received by the filtering and sensing module 4, thereby obtaining a second electromagnetic wave (not shown) with a second wavelength range, wherein the second wavelength range is part of the first wavelength range. Besides, the electromagnetic sensor 1 is disposed under the corresponding non-organic filtering element 3, and is mainly used for receiving the second electromagnetic wave passing through the non-organic filtering element 3. The electron/hole collecting module 5 is electrically connected to the electromagnetic sensor 1. When the distributed filtering and sensing structure 100 is applied on an optical device such as a solar cell, the electron/hole collecting module 5 is used for collecting the electricity generated by the incident electromagnetic wave. When the distributed filtering and sensing structure 100 is applied on an optical device such as a touch control display device, the electron/hole collecting module 5 is used for receiving electrical signals generated from the incident electromagnetic wave, thereby performing a touch control function. In a specific embodiment, the electron/hole collecting module 5 is a device with the structure such as a P-N junction.

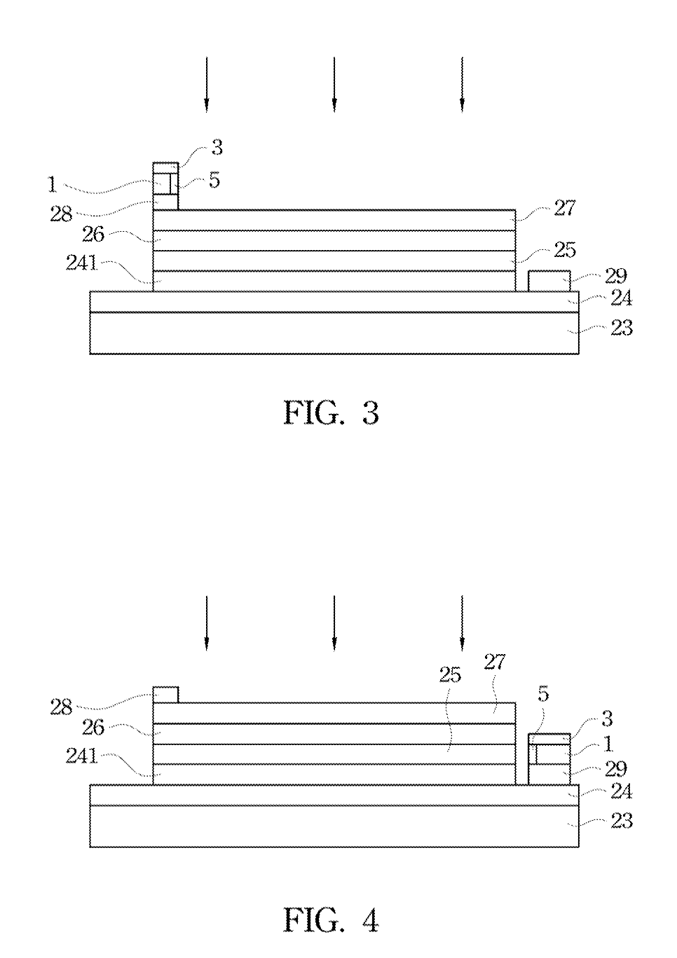

More specifically, in the embodiments shown in FIG. 1A and FIG. 1B, each region 21 of the base board 2 has a sub-region 211, and the filtering and sensing module 4 is disposed in the sub-region 211, wherein the electron/hole collecting module 5 is disposed on one side of the electromagnetic sensor 1. In another embodiment, each region 21 may include a plurality of sub-regions, and thus the number of sub-regions in each region 21 is not limited to that shown in FIG. 1A. With regard to the variations of relative positions among the non-organic filtering element 3, the electromagnetic sensor 1 and the electron/hole collecting module 5, please refer to the structures shown in FIG. 3 to FIG. 22 respectively. However, in a specific embodiment, the position of the electron/hole collecting module 5 is not limited to what have been shown in those figures, and can be changed in accordance with actual needs.

It is noted that, since the distributed filtering and sensing structure 100 is applicable to the optical devices such as a LCD device, a plasma display device, an OLED display device, an LED display device, an LCOS display device, a digital light processing (DLP) display device, a dot matrix display (DMD) device, a touch control display device and a surface-conduction electron emitter display (SED) device, etc. Therefore, each of the aforementioned filtering and sensing modules 4 may further include other necessary components for various display devices.

Further, in the present embodiment, the sub-regions 211 in the regions 21 are equally spaced from one another. However, in a specific embodiment, the sub-regions 211 in the regions 21 can be unequally spaced from one another. Besides, the sub-regions 211 in two adjacent regions can directly contact each other, i.e. zero distance exists therebetween.

In a specific embodiment, the non-organic filtering element 3 includes the patterns of silts, holes, or meshes, etc. for filtering out a portion of the first electromagnetic wave within a specific wavelength range, thereby obtaining the second electromagnetic wave with the second wavelength range. In a specific embodiment, the electromagnetic sensor 1 can be a solar sensor, a photodiode, a CMOS (Complementary Metal Oxide Semiconductor) image sensor, or a CCD (Charge Coupled Device) image sensor, etc.

Further, in a specific embodiment, the second wavelength range to which one of the filtering and sensing modules 4 is corresponding is different from the second wavelength range to which another one of the filtering and sensing modules 4 is corresponding. In other words, the wavelength range filtered by the non-organic filtering element 3 of each filtering and sensing module 4 is not necessary to be the same.

In a display device adopting the distributed filtering and sensing structure 100, a plurality of electromagnetic sensors 1 are distributed within a display screen portion, wherein several electromagnetic sensors 1 can be used as the image capturing device. Accordingly, when the display device adopting the distributed filtering and sensing structure 100 is used to conduct video telephone communication, the users at two different places are able to stare at each other and may communicate with each other like they were face to face in person.

As to various display devices in existing markets, a plurality of electromagnetic sensors (also referred to as image sensors) are concentrated together and a filtering element formed from an organic material (an organic filtering element) is disposed above the electromagnetic sensors for filtering out the electromagnetic wave with the specific wavelength range. Then, a shutter is disposed above the organic filtering element for controlling the amount of electromagnetic wave irradiating the organic filtering element, and thus the organic filtering element does not have the problem of short operation life.

However, as to the distributed filtering and sensing structure 100 of the present invention, it will have fabrication difficulty and result in the increase of fabrication cost if a shutter is desired to be disposed above the non-organic filtering element 3 of each filtering and sensing module 4. Therefore, no shutter described above is disposed above the non-organic filtering element 3 of each filtering and sensing module 4 for controlling the amount of electromagnetic wave irradiating the filtering element. Since no shutter is disposed above each filtering and sensing module 4, the filtering element will confront the problem of short operation life due to long-term irradiation if being formed from an organic material. Hence, in each filtering and sensing module 4 of the present invention, the filtering element has to be formed from a non-organic material, thereby overcoming the problem of short operation life.

Moreover, in a specific embodiment, the material forming the non-organic filtering element 3 in the distributed filtering and sensing structure 100 includes a metallic material, wherein the metallic material can be a metal material such as aluminum, copper, gold, silver, tungsten or an alloy, etc, or a semiconductor metallic material, etc. When an electromagnetic wave irradiates the metallic material forming the non-organic filtering element 3, electrons and surface plasmons occur at the surface of the metallic material, wherein the electrons and surface plasmons may move freely on the surface of the metallic material. However, the electrons and surface plasmons will disappear when the electromagnetic wave stops irradiating the metallic material, and thus no chemical changes will occur on the non-organic filtering element 3, thereby prolonging the operation life of the non-organic filtering element 3. In contrast, as to the conventional organic filtering element formed from an organic material, when the electromagnetic wave irradiates the surface of the organic material, chemical changes are easily caused on the organic material, thus resulting in negative affects on the operation life of the organic filtering element.

In addition, since the non-organic filtering element 3 is formed by using the metallic material, various semiconductor processes such as etching techniques can be used to fabricate various patterns (such as slits, holes or meshes, etc.) required by the non-organic filtering element 3. Further, when being formed from the metallic material, the non-organic filtering element 3 also can be formed simultaneously with the metal circuits of the optical device or other devices using the distributed filtering and sensing structure 100. Therefore, in comparison with the conventional filtering elements formed from the organic material, the non-organic filtering element 3 of the present invention further has the advantage of simple manufacturing process.

Besides being applied on the video telephone communication, the display device using the distributed filtering and sensing structure 100 is also applicable to a touch control display device or a scanning device of a fingerprint recognition system. When an external object or a user touches a display screen portion of the display device, the light coming from the interior of the display device is reflected back to the display device by the external object or the user touching the display device, and then is detected by the electromagnetic sensors 1 in the filtering and sensing modules 4, thereby achieving the purpose of touch control or fingerprint reading.

In the aforementioned embodiment regarding the touch control display device, the light coming from the interior of the display device is visible light, and thus the light reflected by the external object or the user (i.e. the first electromagnetic wave described above) is also visible light. For not interfering with the patterns displayed on the display device, the light reflected by the external object or the user is first filtered by the non-organic filtering element 3 to obtain invisible light with a specific wavelength range (i.e. the second electromagnetic wave described above, such as infrared light) which is received by the electromagnetic sensors 1.

As shown in FIG. 1C, the distributed filtering and sensing structure further includes an internal light source 7 for providing the functions such as touch control, fingerprint reading, etc.

Concretely speaking, in the embodiments shown in FIG. 14 to FIG. 18, when the distributed filtering and sensing structure 100 is applied on an optical device such as a LCD device, the optical device may include an internal light source 8 disposed therein, and the internal light source 8 can be such as an infrared light source used for providing the function such as touch control. For example, when an external object or a user touches a display screen portion of the LCD device, the light emitted from the internal light source 8 is reflected back to the LCD device by the external object or the user touching the LCD device, and then is detected by the electromagnetic sensors 1 in the filtering and sensing modules 4, thereby achieving the purpose of touch control or fingerprint reading.

However, the position of the internal light source 7 or 8 is not limited to those shown in FIG. 1C and FIG. 14 to FIG. 18, and can be adjusted in accordance with different optical devices.

It is noted that the applications of the distributed filtering and sensing structure 100 are not limited to the aforementioned embodiments, and also can be applied on other types of optical devices. It is appreciated that those skilled in the art may make various changes, modification and replacements without departing from the scope or spirit of the invention.

Referring to FIG. 2, FIG. 2 is a schematic side view showing a distributed filtering and sensing structure according to another embodiment of the present invention, wherein the distributed filtering and sensing structure is similar to that shown in FIG. 1, and the same components are labeled with the same reference numbers. However, the same components may have different structures in different figures. Hereinafter, only the different portions between FIG. 2 and FIG. 1B will be explained, and the same portions will not be explained again.

As shown in FIG. 2, each non-organic filtering element 3, each electromagnetic sensor 1 and each electron/hole collecting module 5 included in the distributed filtering and sensing structure are embedded under the top surface of the region 21 on the base board 2. On the contrary, in the distributed filtering and sensing structure sown in FIG. 1B, each electromagnetic sensor 1 and each electron/hole collecting module 5 are disposed on the top surface of the region 21 on the base board 2.

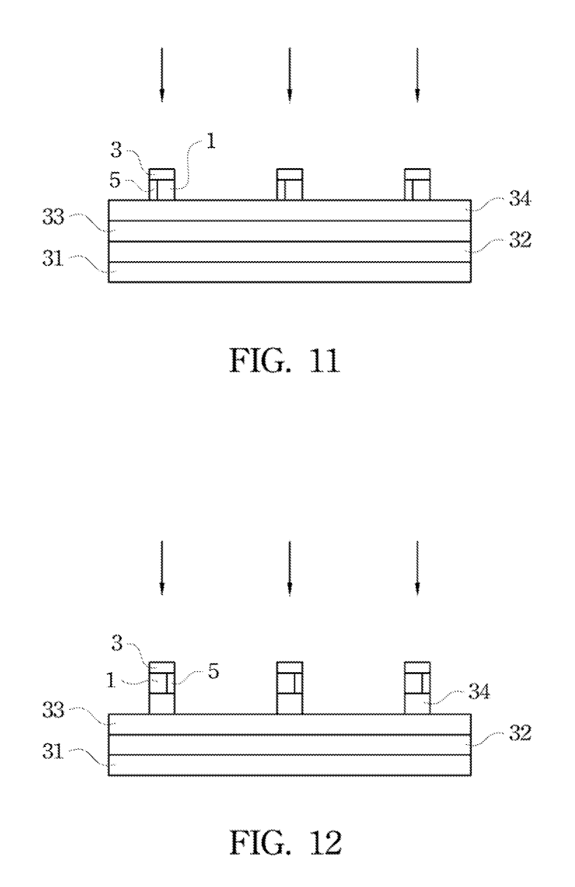

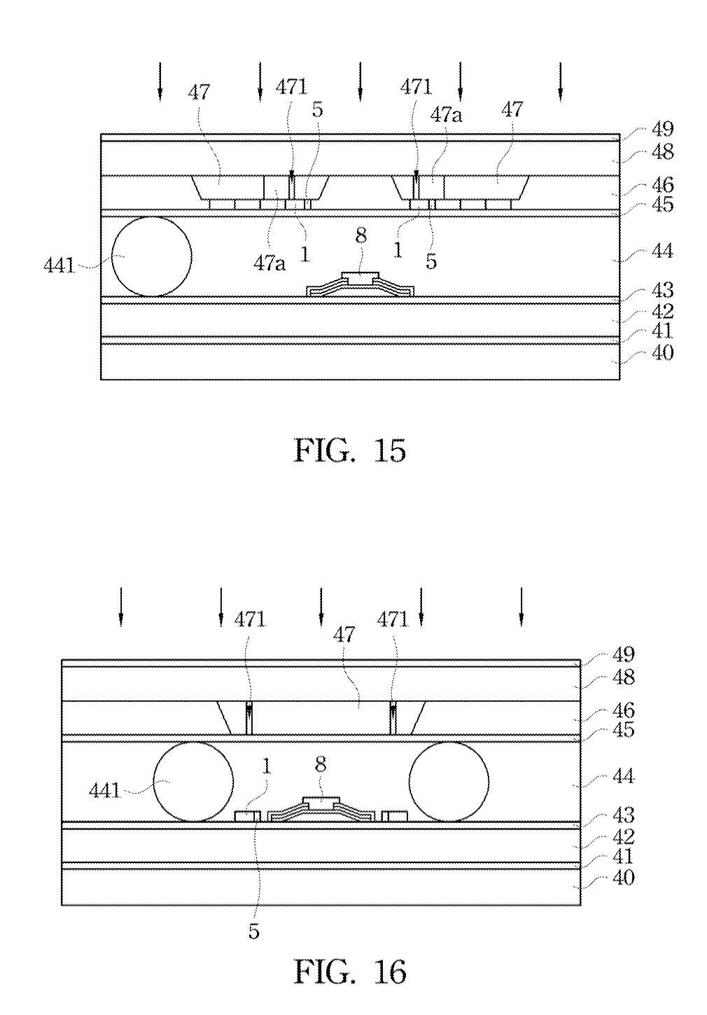

Hereinafter, the embodiments shown in FIG. 3 to FIG. 22 are used for explaining various optical devices on which the distributed filtering and sensing structure of the present invention is applied, wherein the base board 2 shown in FIG. 1B is equivalent to the structure shown in FIG. 3 to FIG. 22 for holding the electromagnetic sensor 1, such as a N-type semiconductor layer 24 shown in FIG. 3; a second electrode 34 shown in FIG. 11; and a first transparent substrate 41 shown in FIG. 15. Further, each region 21 of the base board 22 shown in FIG. 1B may include one or more of the pixel units shown in FIG. 3 to FIG. 22, and on the other hand, one single pixel unit shown in FIG. 3 to FIG. 22 may include one more of the filtering and sensing modules 4 shown in FIG. 1B.

Referring to FIG. 3 to FIG. 10, FIG. 3 to FIG. 10 are schematic side views each of which shows one single pixel unit in an LED display device according to respective embodiments of the present invention.

As shown in FIG. 3, besides the non-organic filtering element 3, the electromagnetic sensor 1 and the electron/hole collecting module 5, the pixel unit further includes a substrate 23, a N-type semiconductor layer 24, a emitting layer 25, a P-type semiconductor layer 26, a current diffusing layer 27, a P-type electrode 28 and a N-type electrode 29, wherein the N-type semiconductor layer 24 includes an extending part 241. The relative positions among the respective components included in the pixel unit are shown in FIG. 3, but are not limited thereto. Those skilled in the art may make various changes, modification and replacements. In the present embodiment, the electromagnetic sensor 1 and the electron/hole collecting module 5 are disposed on the P-type electrode 28, and the non-organic filtering element 3 is disposed on and directly contacts the electromagnetic sensor 1 and the electron/hole collecting module 5. In a specific embodiment, the material forming the substrate 23 can be such as sapphire, silicon, silicon carbide or gallium arsenide.

The structures shown in FIG. 4 to FIG. 10 are similar to the structure shown in FIG. 3, and the same components are labeled with the same reference numbers. However, the same components may have different structures in different figures. Hereinafter, only the different portions between FIG. 4 to FIG. 10 and FIG. 3 will be explained, and the same portions will not be explained again.

The overall structures shown in FIG. 3 and FIG. 4 are similar but different in that, the electromagnetic sensor 1, the non-organic filtering element 3 and the electron/hole collecting module 5 are disposed on the N type electrode 29 in FIG. 4, but on the P-type electrode 28 in FIG. 3.

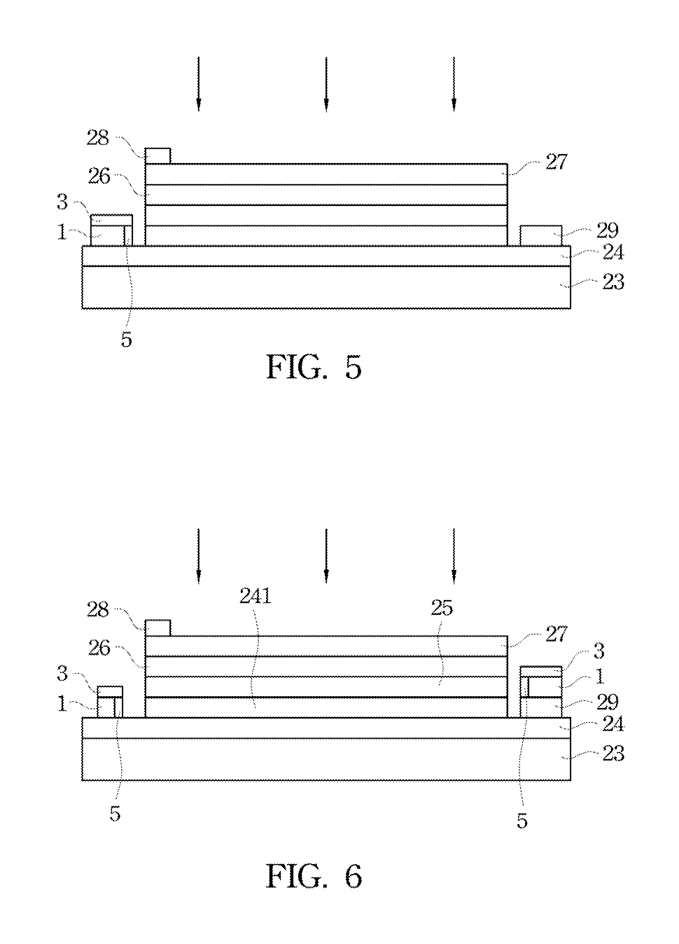

The overall structures shown in FIG. 3 and FIG. 5 are similar but different in that, the electromagnetic sensor 1, the non-organic filtering element 3 and the electron/hole collecting module 5 are disposed on the left edge of the N type semiconductor layer 24 in FIG. 5, but on the P-type electrode 28 in FIG. 3.

As shown in FIG. 6, besides being disposed on the left edge of the N type semiconductor layer 24 as shown in FIG. 5, the electromagnetic sensor 1, the non-organic filtering element 3 and the electron/hole collecting module 5 are further disposed on the N-type electrode 29. In other words, the pixel unit shown in FIG. 6 includes two electromagnetic sensors 1, two non-organic filtering elements 3 and two electron/hole collecting modules 5.

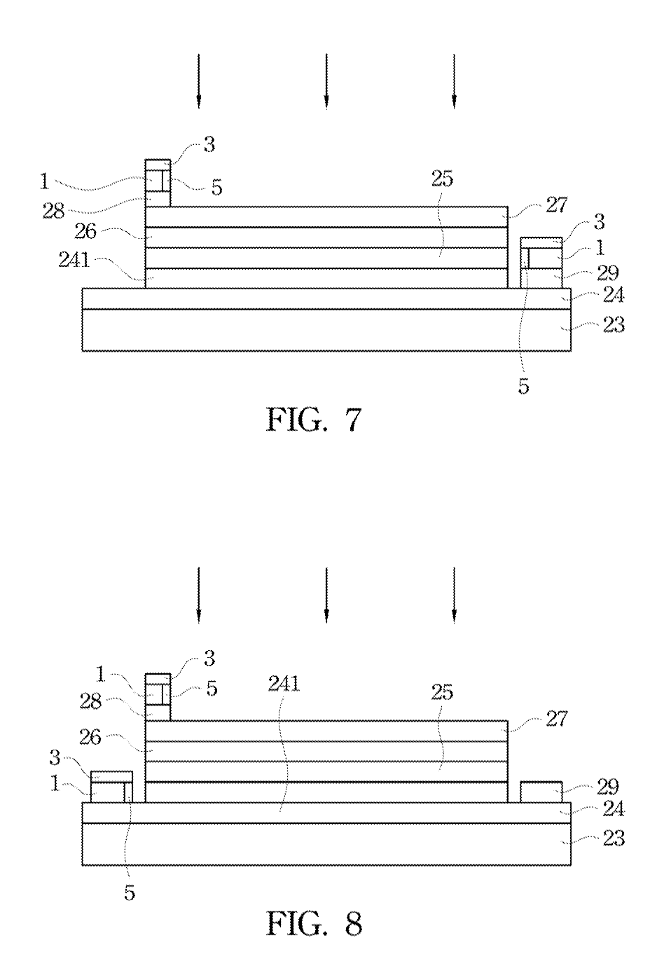

The structures shown in FIG. 7 and FIG. 6 are similar but different in that, the electromagnetic sensor 1, the non-organic filtering element 3 and the electron/hole collecting module 5 are disposed on the P type electrode 28 in FIG. 7, instead of being disposed on the N type semiconductor layer 24 in FIG. 7.

The structures shown in FIG. 8 and FIG. 6 are similar but different in that, the electromagnetic sensor 1, the non-organic filtering element 3 and the electron/hole collecting module 5 are disposed on the P type electrode 28 in FIG. 8, instead of being disposed on the N type electrode 29 in FIG. 6.

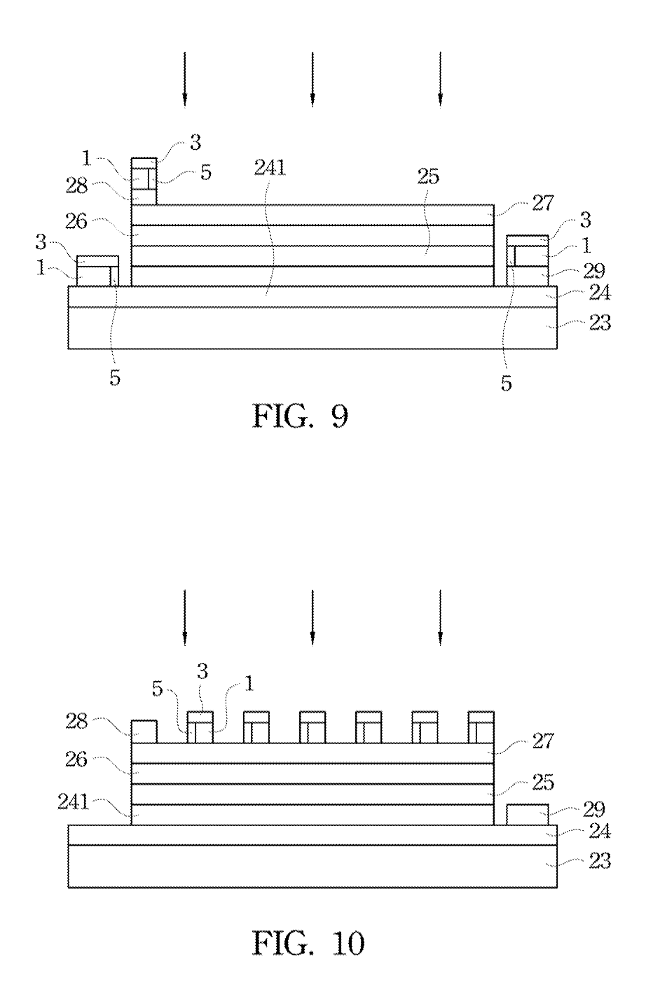

As shown in FIG. 9, the pixel unit includes three sets of electromagnetic sensor 1, non-organic filtering element 3 and electron/hole collecting module 5, wherein one set of electromagnetic sensor 1, non-organic filtering element 3 and electron/hole collecting module 5 is disposed on the N type semiconductor layer 24; another set of electromagnetic sensor 1, non-organic filtering element 3 and electron/hole collecting module 5 is disposed on the P-type electrode 28; and the other set of electromagnetic sensor 1, non-organic filtering element 3 and electron/hole collecting module 5 is disposed on the N-type electrode 29.

As shown in FIG. 10, the pixel unit includes six sets of electromagnetic sensor 1, non-organic filtering element 3 and electron/hole collecting module 5 which are disposed on the current diffusing layer 27 and between the P-type electrode 28 and the N-type electrode 29.

Referring to FIG. 11 to FIG. 13, FIG. 11 to FIG. 13 are schematic side views each of which shows one single pixel unit in an OLED display device according to respective embodiments of the present invention.

Besides the electromagnetic sensor 1, the non-organic filtering element 3 and the electron/hole collecting module 5, the pixel unit further includes a substrate 31, a first electrode 32 formed on the substrate 31, an emitting layer 33 formed on the first electrode 32, and a second electrode 34 formed on the emitting layer 33. The relative positions among the respective components included in the pixel unit are shown in FIG. 11, but are not limited thereto. Those skilled in the art may make various changes, modification and replacements. In the present embodiment, the single pixel unit includes three sets of electromagnetic sensor 1, non-organic filtering element 3 and electron/hole collecting module 5, wherein each electromagnetic sensor 1 and each electron/hole collecting module 5 are disposed on the second electrode 34, and each non-organic filtering element 3 is disposed on the corresponding electromagnetic sensor 1 and electron/hole collecting module 5. In the OLED display device, when the first electrode 32 is a positive electrode, the second electrode 34 is a negative electrode. On the contrary, when the first electrode 32 is a negative electrode, the second electrode 34 is a positive electrode. In addition, the material forming the first electrode 32 and the second electrode 34 can be selected from the materials have high reflective indices or has optionally high index of reflection or high transparency coefficients.

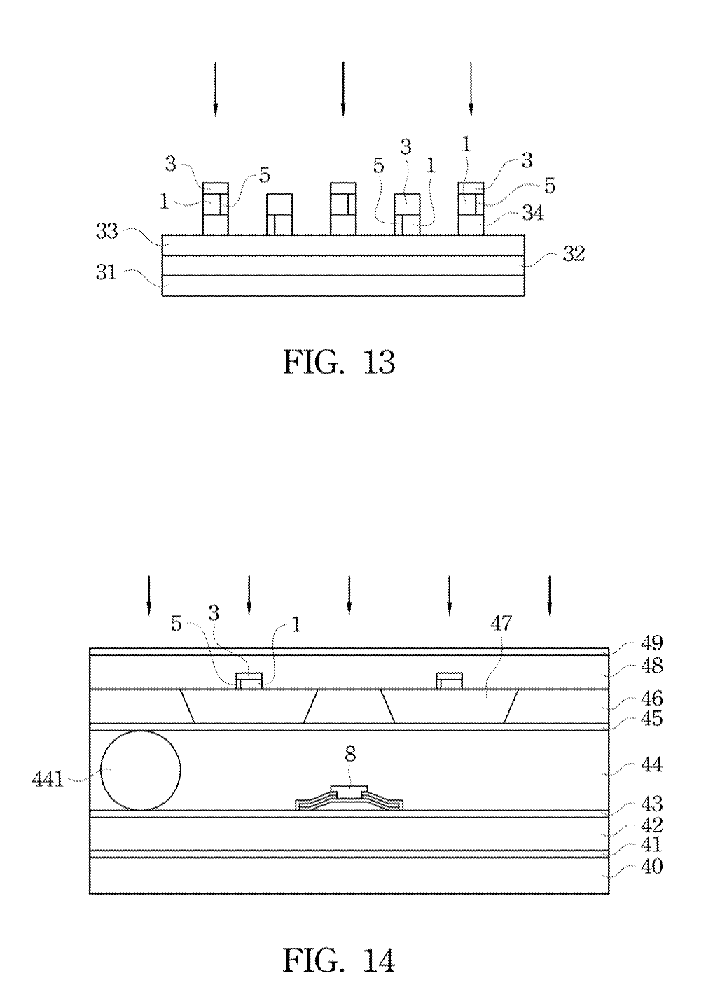

The structures shown in FIG. 12 and FIG. 13 are similar to the structure shown in FIG. 11, and thus the same components are labeled with the same reference numbers. However, the same components may have different structures in different figures. Hereinafter, only the different portions between FIG. 12/FIG. 13 and FIG. 11 will be explained, and the same portions will not be explained again.

The pixel units shown in FIG. 11 and FIG. 12 are similar, and both includes three sets of electromagnetic sensor 1, non-organic filtering element 3 and electron/hole collecting module 5. Those two pixel units are different in that, the second electrode 34 shown in FIG. 11 is a single-piece element, but the second electrodes 34 shown in FIG. 12 are three individual pieces, wherein each piece of second electrode 34 is disposed under one set of electromagnetic sensor 1, non-organic filtering element 3 and electron/hole collecting module 5 correspondingly.

The pixel units shown in FIG. 12 and FIG. 13 are similar, but are different in that, the pixel unit shown in FIG. 13 includes five sets of electromagnetic sensor 1, non-organic filtering element 3 and electron/hole collecting module 5, wherein three sets of electromagnetic sensor 1, non-organic filtering element 3 and electron/hole collecting module 5 are disposed respectively on three pieces of second electrode 34 as shown in FIG. 12, and the other two sets of electromagnetic sensor 1, non-organic filtering element 3 and electron/hole collecting module 5 are disposed on the emitting layer 33.

Referring to FIG. 14 to FIG. 18, FIG. 14 to FIG. 18 are schematic side views each of which shows one single pixel unit in an LCD device according to respective embodiments of the present invention

As shown in FIG. 14, besides the electromagnetic sensor 1, the non-organic filtering element 3 and the electron/hole collecting module 5, the pixel unit further includes a backlight module 40; a first transparent substrate 41 formed on the backlight module 40; a first polarizer 42 formed on the first transparent substrate 41; a TFT (Thin Film Transistor) layer 43 formed on the first polarizer 42; a liquid crystal layer 44 formed on the TFT layer 43; a plurality of spacers 441 formed in the liquid crystal layer 44; a transparent layer 45 formed on the liquid crystal layer 44; a plurality of color filters 46 formed on the transparent layer 45; a plurality of black matrixes 47 embedded in the color filters 46; a second transparent layer 48 formed on the color filters 46 and the black matrixes 47; and a second polarizer 49 formed on the second transparent layer 48. The relative positions among the respective components included in the pixel unit are shown in FIG. 14, but are not limited thereto. Those skilled in the art may make various changes, modification and replacements.

In the present embodiment, the pixel unit includes two sets of electromagnetic sensor 1, non-organic filtering element 3 and electron/hole collecting module 5, wherein each set of electromagnetic sensor 1, non-organic filtering element 3 and electron/hole collecting module 5 is disposed in the second transparent layer 48, and each electromagnetic sensor 1 and each electron/hole collecting module 5 are disposed on the black matrix 47 correspondingly.

The structures shown in FIG. 15 to FIG. 18 are similar to the structure shown in FIG. 14, and thus the same components are labeled with the same reference numbers. However, the same components may have different structures in different figures. Hereinafter, only the different portions between FIG. 15 to FIG. 18 and FIG. 14 will be explained, and the same portions will not be explained again.

As shown in FIG. 15, the electromagnetic sensor 1, the black matrix 47 and the electron/hole collecting module 5 included in the pixel unit are embedded in the color filters 46. Further, the electromagnetic sensor 1 and the electron/hole collecting module 5 are disposed under the black matrix 47. It is noted that the black matrix 47 in the LCD display is generally disposed at the border area between two adjacent pixel units. According to the above description, FIG. 15 shows the border area between two pixel units, and each black matrix at the upper part of the pixel unit includes a second region 47a. Each second region 47a includes a silt pattern 471 used for forming an electromagnetic filtering element. Since the black matrix 47 is generally formed from a metallic material, the electromagnetic filtering element formed from the slit pattern 471 has the same function as the non-organic filtering element 3 shown in FIG. 14. It is noted that only one slit is illustrated in FIG. 15 as an example representing the slit pattern 471, but in an actual structure, a plurality of silts are generally formed in each second unit 47a.

The structures shown in FIG. 16 and FIG. 15 are similar but different in that, the electromagnetic sensor 1 and the electron/hole collecting module 5 included in the pixel unit shown in FIG. 16 are embedded in the liquid crystal layer 44 and disposed under the black matrix 47. In other words, the electromagnetic filtering element formed from the slit pattern 471 for replacing the non-organic filtering element 3 shown in FIG. 14 does not contact the electromagnetic sensor 1 and the electron/hole collecting module 5 directly. In contrast, in the embodiments described previously, the non-organic filtering element 3 directly contacts the electromagnetic sensor 1 and the electron/hole collecting module 5.

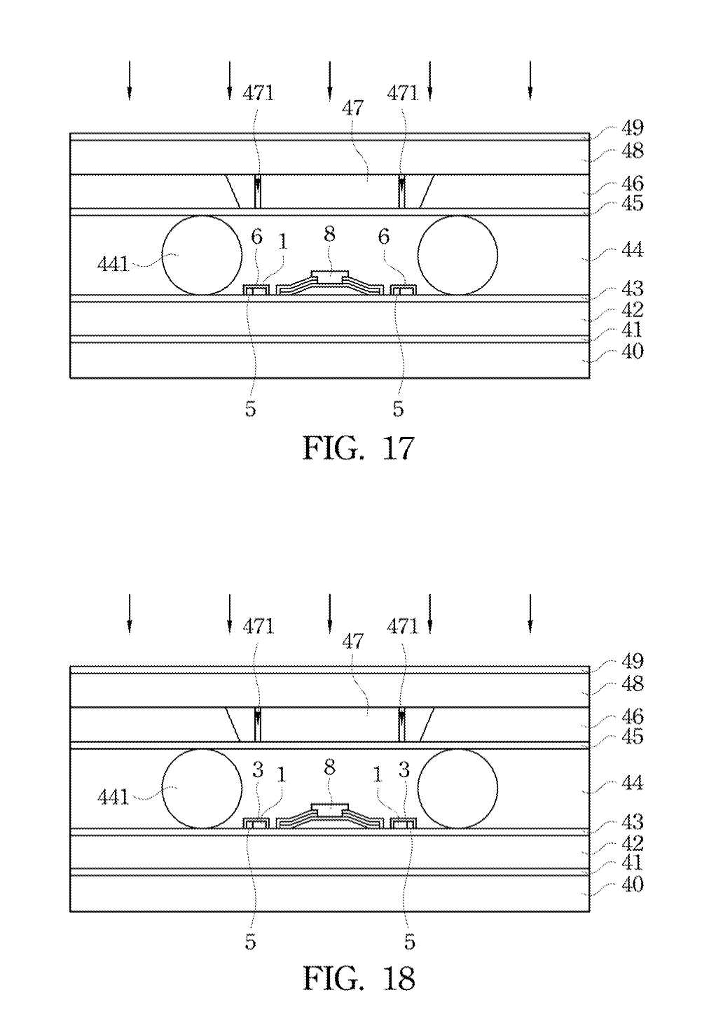

The structures shown in FIG. 17 and FIG. 16 are similar but different in that, the electromagnetic sensor 1 and the electron/hole collecting module 5 included in the pixel unit shown in FIG. 17 are further enclosed by a cover 6 besides being embedded in the liquid crystal layer 44 and disposed under the black matrix 47. In a specific embodiment, the cover 6 can be formed from a dielectric material.

The structures shown in FIG. 18 and FIG. 16 are similar but different in that, the electromagnetic sensor 1 and the electron/hole collecting module 5 included in the pixel unit shown in FIG. 18 further have a non-organic filtering element 3 directly formed thereon besides being embedded in the liquid crystal layer 44 and disposed under the black matrix 47. In other words, in the present embodiment, there are two electromagnetic filtering elements disposed above the electromagnetic sensor 1.

Further, in the aforementioned embodiments shown in FIG. 14 to FIG. 18, the material forming the black matrix 47 can be a metal element or metal oxide. When the distributed filtering and sensing structure 100 is applied on a LCD device, the electromagnetic sensor 1 can be formed simultaneously with the TFT layer 43 for simplifying the overall fabrication process of LCD.

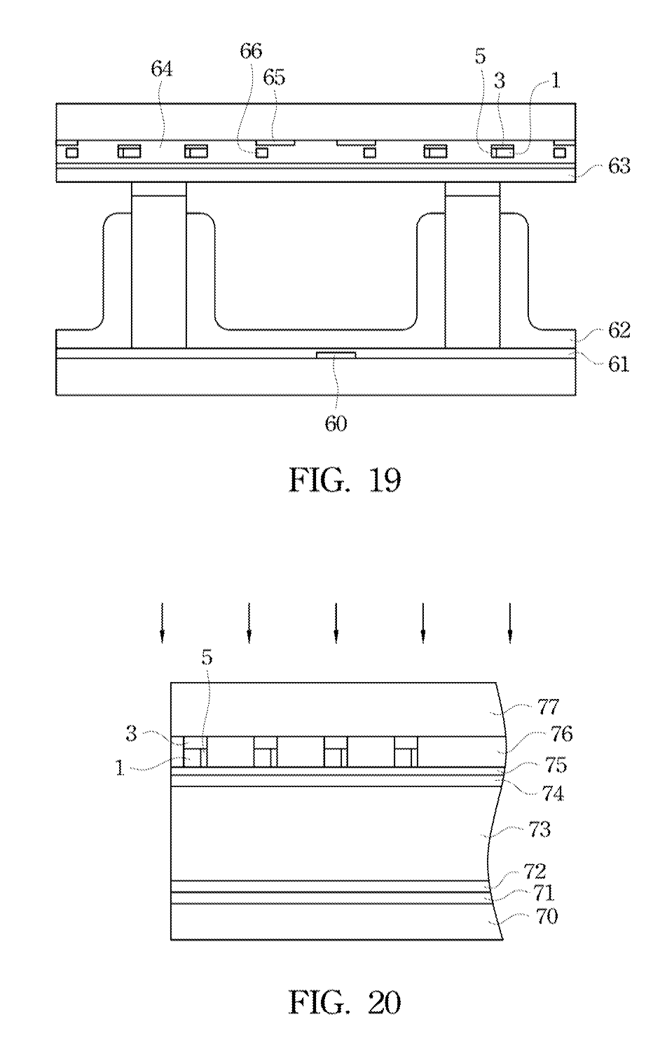

Referring to FIG. 19, FIG. 19 is a schematic side view showing one single pixel unit in a plasma display device according to one embodiment of the present invention.

As shown in FIG. 19, besides the electromagnetic sensor 1, the non-organic filtering element 3 and the electron/hole collecting module 5, the pixel unit further includes a first dielectric layer 61; an address electrode 60 embedded in the first dielectric layer 61; a phosphor layer 62 formed on the first dielectric layer 61; a MgO layer 63 formed on the phosphor layer 62, a second dielectric layer 64 formed on the MgO layer 63; and a plurality of transparent electrodes 65 and a plurality of bus electrodes 66 embedded in the second dielectric layer 64. The relative positions among the respective components included in the pixel unit are shown in FIG. 19, but are not limited thereto. Those skilled in the art may make various changes, modification and replacements. In the present embodiment, the non-organic filtering element 3, the electromagnetic sensor 1 and the electron/hole collecting module 5 are disposed in the second dielectric layer 64.

Referring to FIG. 20 to FIG. 22, FIG. 20 to FIG. 22 are schematic side views each of which shows one single pixel unit in an LCOS device according to respective embodiments of the present invention.

As shown in FIG. 20, besides the electromagnetic sensor 1, the non-organic filtering element 3 and the electron/hole collecting module 5, the pixel unit further includes a first substrate 70; a reflective layer 71 formed on the first substrate 70; a first dielectric layer 72 formed on the reflective layer 71; a liquid crystal layer 73 formed on the first dielectric layer 72; a second dielectric layer 74 formed on the liquid crystal layer 73; an electrically conductive layer 75 formed on the second dielectric layer 74; a color filter layer 76 formed on the electrically conductive layer 75; and a second substrate 77 formed on the color filter layer 76. The relative positions among the respective components included in the pixel unit are shown in FIG. 20, but are not limited thereto. Those skilled in the art may make various changes, modification and replacements. In the present embodiment, a plurality of non-organic filtering elements 3, a plurality of electromagnetic sensors 1 and a plurality of electron/hole collecting modules 5 are disposed in the color filter layer 76.

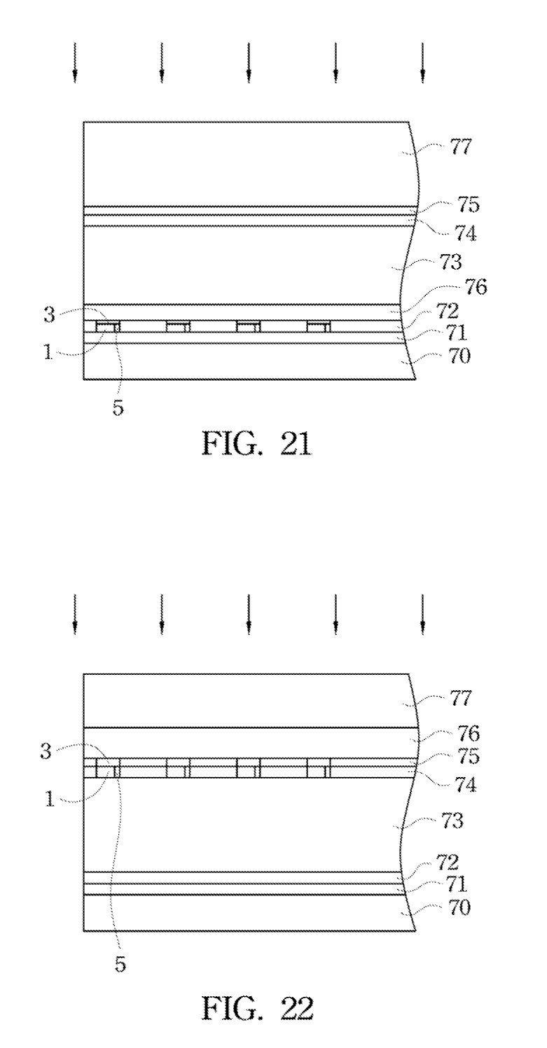

The structures shown in FIG. 21 and FIG. 22 are similar to the structure shown in FIG. 20, and thus the same components are labeled with the same reference numbers. However, the same components may have different structures in different figures. Hereinafter, only the different portions between FIG. 21 and FIG. 22 and FIG. 20 will be explained, and the same portions will not be explained again.

The structures shown in FIG. 21 and FIG. 20 are similar but different in that, the color filter layer 76 shown in FIG. 20 is disposed between the electrically conductive layer 75 and the second substrate 77, but the color filter layer 76 shown in FIG. 21 is disposed between the first dielectric layer 72 and the liquid crystal layer 73. Further, the non-organic filtering element 3, the electromagnetic sensor 1 and the electron/hole collecting module 5 shown in FIG. 20 are disposed in the color filter layer 76, and the non-organic filtering element 3, the electromagnetic sensor 1 and the electron/hole collecting module 5 shown in FIG. 21 are disposed in the first dielectric layer 72.

The structure shown in FIG. 22 and FIG. 20 are similar but different in that, the non-organic filtering element 3, the electromagnetic sensor 1 and the electron/hole collecting module 5 shown in FIG. 20 are disposed in the color filter layer 76, and the non-organic filtering element 3, the electromagnetic sensor 1 and the electron/hole collecting module 5 shown in FIG. 22 are disposed in the electrically conductive layer 75 and the second dielectric layer 74.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A distributed filtering and sensing structure, comprising:
a base board divided into a plurality of regions; and
a plurality of filtering and sensing modules distributed on the regions of the base board, wherein the total number of the filtering and sensing modules is greater than ten, and the total area occupied by the filtering and sensing modules is smaller than one half of the total area of the regions, and each of the filtering and sensing modules is used for receiving a first electromagnetic wave with a first wavelength range, and comprises:
a non-organic filtering element for filtering the first magnetic wavelength to obtain a second electromagnetic wave with a second wavelength range, wherein the second wavelength range is part of the first wavelength range;
an electromagnetic sensor disposed under the non-organic filtering element for receiving the second electromagnetic wave; and
an electron/hole collecting module electrically connected to the electromagnetic sensor.

2. The distributed filtering and sensing structure as claimed in claim 1, wherein the material forming non-organic filtering element comprises a metallic material.

3. The distributed filtering and sensing structure as claimed in claim 1, wherein the second wavelength range to which one of the filtering and sensing modules is corresponding is different from the second wavelength range to which another one of the filtering and sensing modules is corresponding.

4. An optical device, comprising:
a distributed filtering and sensing structure, comprising:
a base board divided into a plurality of regions; and
a plurality of filtering and sensing modules distributed on the regions of the base board, wherein the total number of the filtering and sensing modules is greater than ten, and the total area occupied by the filtering and sensing modules is smaller than one half of the total area of the regions, and each of the filtering and sensing modules is used for receiving a first electromagnetic wave with a first wavelength range, each of the filtering and sensing modules comprising:
a non-organic filtering element for filtering the first magnetic wavelength to obtain a second electromagnetic wave with a second wavelength range, wherein the second wavelength range is part of the first wavelength range;
an electromagnetic sensor disposed under the non-organic filtering element for receiving the second electromagnetic wave; and
an electron/hole collecting module electrically connected to the electromagnetic sensor.

5. The optical device as claimed in claim 4, wherein the material forming non-organic filtering element comprises a metallic material.

6. The optical device as claimed in claim 4, wherein the second wavelength range to which one of the filtering and sensing modules is corresponding is different from the second wavelength range to which another one of the filtering and sensing modules is corresponding.

7. The optical device as claimed in claim 4, wherein the optical device is a solar cell.

8. The optical device as claimed in claim 4, wherein the optical device is a display device.

9. The optical device as claimed in claim 4, further comprising:
an internal light source.

10. The optical device as claimed in claim 9, wherein the internal light source is an infrared light source.
